(19) United States
(12) Patent Application Publication
(10) Pub. No.: US 2023/0021522 A1
(43) Pub. Date: Jan. 26, 2023

(54) COMPONENT AND METHOD FOR PRODUCING A COMPONENT

(71) Applicant: ams-OSRAM International GmbH, Regensburg (DE)

(72) Inventors: Matthias GOLDBACH, Pentling (DE); Georg BOGNER, Hainsacker/Lappersdorf (DE)

(21) Appl. No.: 17/788,238

(22) PCT Filed: May 14, 2021
(86) PCT No.: PCT/EP2021/062851

§ 371 Date: Jun. 22, 2022

(30) Foreign Application Priority Data
May 15, 2020 (DE) 10 2020 113 237.9

(51) Int. Cl. H01L 25/075; H01L 33/48; H01L 33/50; H01L 33/60; H01L 33/62

(52) U.S. Cl. CPC H01L 25/0753; H01L 33/483; H01L 33/50; H01L 33/60; H01L 33/62; H01L 2933/0066

(57) ABSTRACT

The invention relates to a component (100) having an electrically insulating and radiation-transparent substrate (9) and at least one semiconductor chip (10) arranged on the substrate (9). The semiconductor chip (10) is designed to generate electromagnetic radiation and has a front side (11) and a rear side (12) facing away from the front side (11), wherein the front side (11) of the semiconductor chip (10) faces the substrate (9) and is designed as a radiation exit face of the semiconductor chip (10), and wherein the rear side (12) of the semiconductor chip (10) faces away from the substrate (9), wherein the semiconductor chip (10) can be electrically contacted externally via the rear side (12). The invention further relates to a method for producing such a component.

A component, in particular a component for backlighting, is specified. In addition, a method for producing such a component is specified.

For direct backlighting, large numbers of small light emitting diodes (LEDs) are often used to achieve a homogeneous illumination. However, a component with a large number of LEDs can be expected to incur increased costs. Often multiple 360° emitting LEDs are required, which can be mounted in particular on lead frames. However, such a device often has a width or a length of several centimeters and is not particularly suitable for many applications.

One object is to specify a compact component of reduced size and having improved optical properties. A further object of the invention is to specify a simplified and cost-effective method for producing such a component.

These objects are achieved by the component and by the method for producing such a component according to the independent claims. Further designs and refinements of the method or the component are the subject matter of the additional claims.

In at least one embodiment of a component, it comprises an electrically insulating and radiation-transparent substrate and at least one semiconductor chip arranged on the substrate. the semiconductor chip is designed to generate electromagnetic radiation and has a front side and a rear side facing away from the front side. The front side of the semiconductor chip faces the substrate and is also designed as a radiation exit surface of the semiconductor chip. The rear side of the semiconductor chip faces away from the substrate, the semiconductor chip being electrically contactable externally via the rear side.

Such a component may contain a plurality of radiation-emitting semiconductor chips. The component is designed in particular for backlighting. If the semiconductor chip or the plurality of the semiconductor chips is arranged on the substrate, the component can be designed to be particularly stable and robust against shearing forces. The single semiconductor chip or the plurality of semiconductor chips can exhibit a 360° light emission, wherein the emission can be configured, for example due to the arrangement of the semiconductor chips, in such a way that a homogeneous illumination in terms of brightness and color is directed onto a display to be illuminated.

According to at least one embodiment of the component, it is designed as a backlight film. The component can thus be used as a kind of thin backlight film in which the surface of the component or the backlight film can have a warm-white, cold-white, or multi-colored appearance, for example in the case of components with RGB semiconductor chips or with converter layers. For example, the component or backlight film has a total vertical thickness of less than 5 mm, 3 mm, 2 mm, 1 mm or less than 0.5 mm, e.g. between 0.1 mm and 1 mm inclusive, or between 0.1 mm and 0.5 mm inclusive.

According to at least one embodiment of the component, the substrate has a transmittance for visible light of between 15% and 95%, 15% and 85%, 15% and 75%, 15% and 65%, 15% to 55% or between 15% and 45%, inclusive in each case. For example, electromagnetic radiation is coupled into the substrate at a main surface of the substrate facing the semiconductor chip and decoupled from the substrate at a main surface of the substrate facing away from the semiconductor chip. The rest of the light coupled into the substrate can be emitted at the side surfaces of the substrate. For example, the substrate has a transmittance for visible light of 30%±15%, 30%±10%, 30%±5%. The substrate is a glass panel or a glass substrate, for example.

According to at least one embodiment of the component, the substrate has a structured surface facing the semiconductor chip, wherein the transmittance of the substrate is set by the structuring of the surface.

According to at least one embodiment of the component, the semiconductor chip has a converter layer with phosphors, wherein the phosphors are designed to convert short-wave radiation components into long-wave radiation components. For example, the front side of the semiconductor chip is formed by one surface of the converter layer.

According to at least one embodiment of the component, the semiconductor chip has a semiconductor body with a first semiconductor layer of a first charge carrier type, with a second semiconductor layer of a second charge carrier type, and an active zone arranged between the semiconductor layers. The active zone is designed in particular for generating electromagnetic radiation and can be a pn-junction zone. The semiconductor chip may have a first contact layer on the rear side for electrically contacting the first semiconductor layer and/or a second contact layer for electrically contacting the second semiconductor layer.

According to at least one embodiment of the component, the semiconductor chip has a via which extends along a vertical direction through the first semiconductor layer and through the active zone into the second semiconductor layer, wherein the via is designed for electrically contacting the second semiconductor layer. In particular, the via is electrically conductively connected to the second contact layer.

A vertical direction is understood to mean a direction that is, in particular, perpendicular to a main extension surface of the substrate. A lateral direction is understood to mean a direction that runs, in particular, parallel to a main extension surface of the substrate. The vertical direction and the lateral direction are approximately orthogonal to each other.

According to at least one embodiment of the component, it has at least one electrically insulating molded body which is arranged on the substrate and encloses the semiconductor chip in lateral directions, in particular completely enclosing it. In particular, the semiconductor chip is separated from the molded body in lateral directions by an intermediate region, wherein the intermediate region can be filled with an electrically insulating and/or radiation reflecting material.

According to at least one embodiment of the component, it has at least one first bonding pad and one second bonding pad, wherein each of the bonding pads covers some regions of the molded body and the semiconductor chip when the substrate is viewed from above. The bonding pads can each be electrically conductively connected to one of the contact layers of the semiconductor chip. For example, the bonding pads are formed by planar contact structures, which are in particular flat and do not have any vertical branches, for example. In particular, the bonding pads are formed as planar contacts (Planar Inter-Connect) of the component.

According to at least one embodiment of the component, a solder ball is arranged on each of the bonding pads. The solder balls are designed in particular to establish a mechanical and electrical connection of the component to a target mounting surface and at the same time to compensate for height differences on the rear side of the component.

According to at least one embodiment of the component, it comprises a plurality of radiation-emitting semiconductor chips which are arranged side by side on the substrate. The features disclosed here in connection with a component that has at least one semiconductor chip can also be used for a component having a plurality of radiation-emitting semiconductor chips.

In an embodiment for producing a component, in particular a component described here, a prefabricated semiconductor chip or a plurality of prefabricated semiconductor chips is adhesively bonded onto the substrate. The semiconductor chip or the plurality of the semiconductor chips is at least laterally encased with an electrically insulating material in order to form a molded body. A plurality of bonding pads can be formed on the molded body and on the rear side of the semiconductor chip, wherein each of the bonding pads covers some regions of the molded body and the semiconductor chip when the substrate is viewed from above. Each of the bonding pads can be electrically conductively connected to one of the contact layers of the semiconductor chip or the plurality of the semiconductor chips. In particular, the bonding pads each have a larger cross-section than the corresponding contact layers of the semiconductor chips.

In accordance with at least one embodiment of the method, the bonding pads are produced by means of planar interconnect.

According to at least one embodiment of the method, the molded body is formed by means of a forming process, in particular by means of a film-assisted forming process. Various molding processes can also be used to shape the component and achieve suitable radiation characteristics, in particular to produce the converter layer and/or a, for example, semi-transparent and reflective covering layer, and/or the molded body.

The method described above for producing a component is particularly suitable for producing a component described here having at least one semiconductor chip or a plurality of semiconductor chips. The features described in connection with the component can therefore also be applied to the method and vice versa.

In all exemplary embodiments of a component or a method for producing a component described here, the invention may provide the following solutions.

The semiconductor chips, for example in the form of thin-film flip chips, in particular in the form of thin-film LEDs, can be mounted with their light-emitting sides on the substrate, for example in the form of a glass panel, glass plate or glass foil, with the substrate being already designed such that the light distribution is optimally adapted to the requirements for direct backlighting.

For RGB displays, LEDs emitting white light are preferred. For example, blue light emitting thin-film LEDs with an additional converter film are used. The thin-film LEDs can be produced in such a way that the required converter film is applied to a thin-film flip-chip wafer in the wafer process. The flip chips can then be separated and applied to a, in particular transparent, milky glass plate, for example with 30% transparency. The glass panel or glass plate can have a surface finish that controls the transparency. Coupled-in light that is not decoupled at a front side of the substrate may be absorbed by the substrate or may emerge from the component at side surfaces of the substrate.

Separating slits can be formed between the LEDs, which are filled with plastic, photoresist and/or with reflective particles, for example by coating or by a film-assisted molding process. For example, a white reflective layer is first deposited, and the separating slits are then filled with photoresist, for example with Peterslack, in a subsequent method step.

Electrical contact layers of the semiconductor chip can be exposed and bonding pads can be formed, for example by means of a so-called planar interconnect method (PICOS). The PICOS method can be used to increase the size of the electrical contact layers of the semiconductor chip. For example, surfaces such as Cu surfaces of the planar interconnect layers can be protected by an organic coating. At designated points, the connection pads can be fitted with solder balls, so that a kind of ball grid array is formed. With these solder balls, height differences can be compensated and an optimal soldering behavior can be achieved. If necessary, the components can be singulated and measured.

Since the substrate can be produced in the form of a glass panel of any size and adapted to the optimum beam distribution, and since the bonding pads, in particular designed to be planar, can be formed in any size on the substrate, a number of optimum properties of the component can be combined with one another. For example, a low-cost substrate material with optimized light-emitting properties can be used for the substrate. Thin-film technology without light loss to the sides can be applied. By using large-area substrates, low-cost electrical contacting means can be achieved, for example, due to the planar interconnect. The enlargement of the electrical connection points of the semiconductor chip is thus accomplished in a cost-effective manner. The ball grid array creates a balance during assembly, which makes it possible to place the semiconductor chips, e.g. in the form of flip-chips, on low-cost substrates or films while still ensuring the required high mechanical stability of the component.

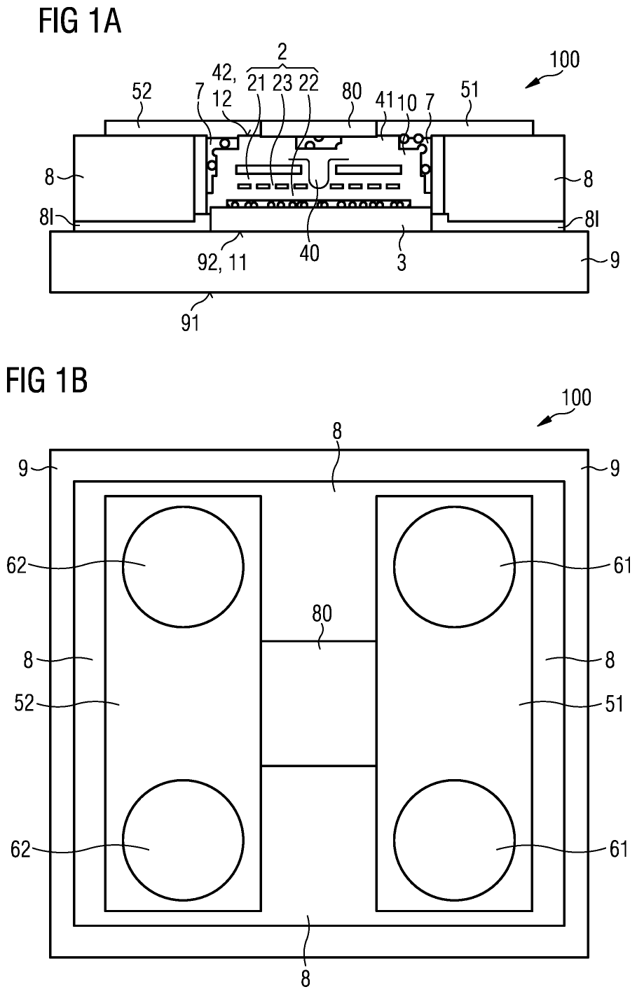

Further advantageous embodiments and refinements of the component and the method for producing the component or a plurality of components are obtained from the exemplary embodiments, described hereafter in connection with FIGS. 1A to 3B. In the drawings:

FIGS. 1A and 1B show schematic diagrams of an exemplary embodiment of a component,

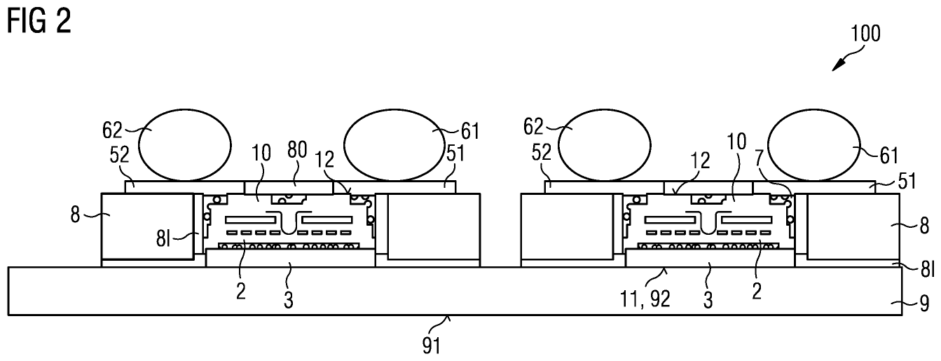

FIG. 2 shows a schematic diagram of another exemplary embodiment of a component in a sectional view, and

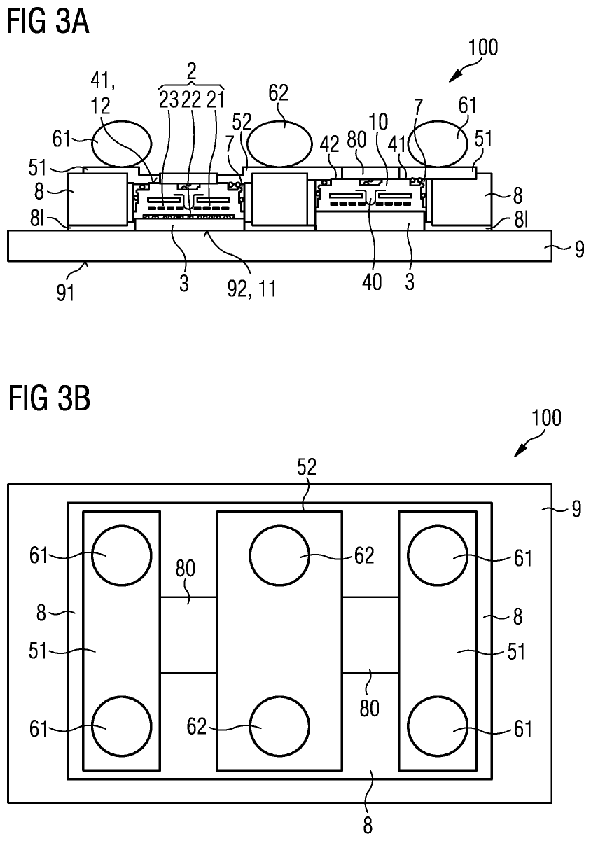

FIGS. 3A and 3B show schematic diagrams of another exemplary embodiment of a component in sectional view and in plan view.

Identical, similar or equivalently functioning elements are labelled with identical reference signs in the figures. The figures are all schematic representations and therefore not necessarily true to scale. Rather, comparatively small elements and, in particular, layer thicknesses can be displayed excessively large for clarity.

FIG. 1A shows a component 100 in a sectional view. The component 100 comprises a substrate 9 on which a semiconductor chip 10 is arranged. The semiconductor chip 10 is in particular a radiation-emitting flip-chip. The substrate 9 is designed to be radiation-transparent and can be a glass panel. The semiconductor chip 10 is arranged on the substrate 9 in such a way that a front side 11 of the semiconductor chip 10, which is designed in particular as a radiation exit surface of the semiconductor chip 10, faces the substrate 9. In particular, except for a connecting layer, the front side 11 of the semiconductor chip 10 can be directly adjacent to the substrate 9, for example, to a rear side 92 of the substrate 9. The substrate 9 has a front side 91 which is designed in particular as a radiation exit surface of the component 100. The front 91 and/or the rear 92 can be structured to adjust the transmittance of the substrate 9.

The semiconductor chip 10 has a semiconductor body 2 and a converter layer 3 arranged on the semiconductor body 2. The front side 11 of the semiconductor chip 10 is formed by a surface of the converter layer 3. The semiconductor body 2 has a first semiconductor layer 21, a second semiconductor layer 22, and an active zone 23 arranged between the first semiconductor layer and the second semiconductor layer 22. The first semiconductor layer 21 is facing away from the substrate 9. The second semiconductor layer 22 faces the substrate 9. It is possible to design the first semiconductor layer 21 to be n-type and the second semiconductor layer 22 to be p-type, or vice versa. Both the first semiconductor layer 21 and the second semiconductor layer 22 can be designed as a single layer or as a layer sequence.

An active zone 23 of the semiconductor body 2 is understood to mean an active region in the semiconductor body 2, which is designed in particular for generating electromagnetic radiation. In the operation of the component 100, the active zone 23 is configured, for example, to generate electromagnetic radiation in the ultraviolet, the visible, for example in the blue, or in the infrared spectral range. For example, the active zone 23 comprises a pn-junction zone or an accumulation of quantum structures that is/are designed for generating electrical radiation.

The semiconductor chip 10 has a first electrical contact layer 41 and a second electrical contact layer 42 on its rear side 12. The contact layers 41 and 42 are assigned to different electrical polarities of the semiconductor chip 10. In particular, the first electrical contact layer 41 is designed for electrically contacting the first semiconductor layer 21. The second electrical contact layer 42 is designed for electrically contacting the second semiconductor layer 22. Furthermore, the semiconductor chip 10 has a via 40 which is electrically conductively connected to the second electrical contact layer 42, for example, and is thus designed for electrically contacting the second semiconductor layer 22. Along the vertical direction, the via 40 can extend through the first semiconductor layer 21 and through the active zone 23 into the second semiconductor layer 22.

The component 100 has a molded body 8, which is arranged on the substrate 9. The semiconductor chip 10 can be partially or completely enclosed in lateral directions by the molded body 8. It is possible that the component 100 has a plurality of semiconductor chips 10, which are each partially or completely enclosed in lateral directions by the molded body 8. In a plan view of the rear side of the component 100, the molded body 8 can have openings in which the semiconductor chips 10 are arranged. In lateral directions, intermediate regions 7 can be located between the molded body 8 and the semiconductor chip 10. The intermediate regions 7 may be filled with electrically insulating materials, radiation-reflecting particles, and/or by the photoresist. An insulation layer 81 can be formed in the intermediate regions 7 between the molded body 8 and the semiconductor chip 10. In FIG. 1A, an insulation layer 8I is arranged in a vertical direction between the mold 8 and the substrate 9 in some regions.

The rear side of the component 100 has a first bonding pad 51 and a second bonding pad 52. The first bonding pad 51 is electrically conductively connected, in particular to the first contact layer 41. The second bonding pad 52 is electrically conductively connected to the second contact layer 42, for example. In plan view, the bonding pads 51 and 52 cover both the molded body 8 and the contact layer 41 or 42. In particular, the bonding pads 51 and 52 have larger cross-sections than the associated contact layers 41 and 42. For electrical insulation, an insulation layer 80 is arranged between the first bonding pad 51 and the second bonding pad 52.

In FIG. 1B, the component 100 according to FIG. 1A is illustrated schematically in plan view. On the respective bonding pads 51 and 52, solder balls 61 and 62 can be arranged. According to FIG. 1B, two solder balls 61 are arranged on the first bonding pad 51. Two solder balls 62 are also arranged on the second bonding pad 52. In particular, the solder balls 61 and 62 form a ball grid array.

The component 100 shown in FIG. 1A or 1B can have a total vertical height of less than 5 mm, 3 mm, 1 mm, or less than 0.5 mm. For example, the vertical height can be between 200 μm and 5 mm inclusive, between 200 μm and 1 mm inclusive, or between 200 μm and 500 μm inclusive, for example between 300 μm and 400 μm inclusive. The component 100 can have a lateral length or a lateral width that is less than 5 mm, 3 mm, 1 mm, 0.5 mm, e.g. between 0.5 mm and 5 mm inclusive. For example, the component 100 has a cross-section of approximately 500 μm×500 μm, 500 μm×1 mm, 500 μm×2 mm, 500 μm×3 mm, 500 μm×5 mm, or 1 mm×1 mm, 1 mm×2 mm, 1 mm×3 mm or 1 mm×5 mm. In particular, the component 100 has a cross-section that is less than 1.5 mm×1.5 mm, 1.5 mm×2 mm, 1.5 mm×3 mm, 1.5 mm×5 mm, or 1.5 mm×5 mm.

The component 100 shown in FIG. 2 corresponds essentially to the component 100 illustrated schematically in FIG. 1A. In contrast, the component 100 can have a plurality of semiconductor chips 10 instead of a single semiconductor chip 10. It is possible that the component 100 has a plurality of semiconductor chips 10 which are arranged on the substrate 9 in rows and columns.

According to FIG. 2, the molded body 8 can have a plurality of separate subregions, each of which laterally encloses at least one semiconductor chip 10, in particular enclosing it completely. There are thus separating slots between the subregions of the molded body 8. At the separating slots, the component 100 can be singulated into a plurality of smaller components 100. Contrary to FIG. 2, it is possible for the molded body 8 to be formed contiguously. All features described in connection with the component 100 shown in FIG. 1A can also be used for the component 100 shown in FIG. 2.

The exemplary embodiment of a component 100 illustrated in FIGS. 3A and 3B corresponds essentially to the exemplary embodiment of a component 100 illustrated in FIGS. 1A and 1B. In contrast to this, the component 100 has a plurality of semiconductor chips 2, which are shown schematically in a similar way to FIG. 2. In contrast to that, no separating slots are formed between the subregions of the molded body 8. The molded body 8 according to FIGS. 3A and 3B is designed in particular contiguously and as a single piece.

Two adjacent semiconductor chips 10 or two adjacent rows of semiconductor chips 10 can have a common bonding pad 52, which is shown schematically in FIG. 1B, for example. Due to the differences in height between the molded body 8 and the semiconductor chip 10, a bonding pad 51 or 52 can have the shape of a step in some regions. All features described in connection with the component 100 shown in FIGS. 1A, 1B and 2 can also be used for the component 100 shown in FIGS. 3A and 3B, or vice versa.

This patent application claims priority over the German patent application DE 10 102020 113 237.9, the disclosed content of which is hereby incorporated by reference.

The invention is not limited to the embodiments by the fact that the description of the invention is based on them. Rather, the invention comprises each new feature, as well as any combination of features, which includes in particular any combination of features in the patent claims, even if this feature or this combination itself is not explicitly specified in the patent claims or exemplary embodiments.

### LIST OF REFERENCE SIGNS

100 component

10 semiconductor chip

11 front side of semiconductor chip

12 rear side of semiconductor chip

2 semiconductor body

21 first semiconductor layer

22 second semiconductor layer

23 active zone

3 converter layer

40 via

41 first contact layer

42 second contact layer

51 first bonding pad

52 second bonding pad

61 solder ball

62 solder ball

7 intermediate region

8 molded body

80 insulation layer

81 insulation layer

9 substrate

91 surface/front side of the substrate

92 surface/rear side of the substrate

1. A component comprising:
an electrically insulating and radiation-transparent substrate; and
at least one semiconductor chip arranged on the substrate (9),
wherein:
the at least one semiconductor chip is designed to generate electromagnetic radiation and has a front side and a rear side facing away from the front side,
the front side of the at least one semiconductor chip (10) faces the substrate and is designed as a radiation exit surface of the at least one semiconductor chip,
the substrate has a transmittance of at least 30%±15% for visible light, and
the rear side of the at least one semiconductor chip faces away from the substrate, the at least one semiconductor chip being electrically contactable externally via the rear side.

2. The component as claimed in claim 1, in which the substrate is a glass panel having the transmittance for the visible light of between 15% and 95% inclusive.

3. (canceled)

4. The component as claimed in claim 1, in which the substrate has a structured surface facing the at least one semiconductor chip, the transmittance of the substrate being set by the structuring of the surface.

5. The component as claimed in claim 1, in which the at least one semiconductor chip has a converter layer containing phosphors, the phosphors being designed to convert short-wave radiation components into long-wave radiation components, and the front side of the at least one semiconductor chip being formed by a surface of the converter layer.

6. The component as claimed in claim 1, in which the at least one semiconductor chip has a semiconductor body with a first semiconductor layer of a first charge carrier type, with a second semiconductor layer of a second charge carrier type, and an active zone arranged between the first semiconductor layer and the second semiconductor layer, the at least one semiconductor chip having a first contact layer on the rear side for electrically contacting the first semiconductor layer and a second contact layer for electrically contacting the second semiconductor layer.

7. The component as claimed in claim 6, in which the at least one semiconductor chip has a via extending along a vertical direction through the first semiconductor layer and the active zone into the second semiconductor layer, wherein the via is designed for electrically contacting the second semiconductor layer and is electrically conductively connected to the second contact layer.

8. The component as claimed in claim 1, which has at least one electrically insulating molded body, arranged on the substrate and completely enclosing the at least one semiconductor chip in lateral directions.

9. The component as claimed in claim 8, in which the at least one semiconductor chip is separated from the at least one molded body in the lateral directions by an intermediate region, the intermediate region being filled with an electrically insulating and/or radiation reflecting material.

10. The component as claimed in claim 8, which has at least one first bonding pad and at least one second bonding pad, wherein each of the at least one first bonding pad and the at least one second bonding pad covers some regions of the at least one molded body and the at least one semiconductor chip when the substrate is viewed from above.

11. The component as claimed in claim 10, in which at least one solder ball is arranged on each of the at least one first bonding pad and the at least one second bonding pad, each solder ball being designed to create a mechanical and electrical connection of the component to a target mounting surface and at a same time to compensate for height differences on a rear side of the component.

12. The component as claimed in claim 1, which comprises a plurality of radiation-emitting semiconductor chips which are arranged side-by-side on the substrate.

13. A method for producing the component as claimed in claim 1, in which:
the at least one semiconductor chip is adhesively bonded to the substrate,
the at least one semiconductor chip is at least laterally encased with an electrically insulating material to form a molded body, and
bonding pads are formed on the molded body and on the rear side of the at least one semiconductor chip, wherein each of the bonding pads covers some regions of the molded body and the at least one semiconductor chip when the substrate is viewed from above.

14. The method as claimed in claim 13, in which the bonding pads are produced by planar electrical interconnect.

15. The method as claimed in claim 13, in which the molded body is formed by a film-assisted forming process.
